(19) United States
(12) Patent Application Publication
(10) Pub. No.: US 2011/0293231 A1
(43) Pub. Date: Dec. 1, 2011

(54) OPTICAL FACEPLATE AND METHOD OF MANUFACTURE

(75) Inventors: Ties van Bommel, Horst (NL); Rifat Ata Mustafa Hikmet, Eindhoven (NL); Hans van Sprang, Waalre (NL); Marcus Antonius Verschuuren, Oisterwijk (NL)

(73) Assignee: KONINKLIJKE PHILIPS ELECTRONICS N.V., EINDHOVEN (NL)

(21) Appl. No.: 12/787,854

(22) Filed: May 26, 2010

(51) Int. Cl. G02B 6/04; C23C 14/28; B05D 5/06

(52) U.S. Cl. 385/120; 427/163.2; 427/595

(57) ABSTRACT

Optical faceplates and methods for manufacturing same are disclosed. An optical faceplate (10) includes a substrate (12) having a major surface, and an array (15) of optical fibers embossed on the substrate. The optical fibers have a length determined in accordance with a layer of material deposited on the substrate from which the optical fibers are formed, a depth of the features in a mold or stamp and a number of processing/stamping steps. A method includes forming (202) a layer on a substrate having a major surface, and processing (204) the layer to form an array of optical fibers transversely disposed to the major surface.

This disclosure relates to optical faceplates used in various applications including light and image transfer, and more particularly to optical faceplates and manufacturing methods that employ embossed optical fibers transversely disposed to an optical substrate.

Fiber optic faceplates, in which light is transmitted from or to a source or detector, are used for high resolution, zero thickness light and image transfer in applications that may include CCD/CMOS coupling, laser array/fiber array coupling, CRT/LCD displays, image intensification, remote viewings, field flattening, X-ray imaging, and molecular diagnostics like in genomics, proteomics, drug discovery and micro-fluidic systems. Although the advantages of fiber optics are clear and proven, various problems and limitations exist in manufacturing these plates.

Current problems in manufacturing of optical faceplates include difficulties in bundling thin optical fibers to a desired diameter, bonding them together followed by cutting and polishing the bundled fibers to the desired thickness. There is also room for improvement in manufacturing faceplates with fibers having smaller sizes (below 10 micron), to control diameter and parallel alignment between the individual fibers. In addition, current manufacturing processes do not provide an efficient way to vary the center-to-center spacing between the fibers, and do not provide differently shaped fibers (e.g. ovals, squares, hexagons, octagons, etc.).

Another recognized problem is providing the precise alignment of the fibers with respect to the pixels of a detector, such as CCD or CMOS sensors to avoid cross talk. The complexity of conventional face plate fabrication results in an expensive manufacturing process.

In accordance with present embodiments, optical faceplates and methods for manufacturing same are disclosed. An optical faceplate includes a substrate having a major surface, and an array of optical fibers embossed on the substrate. The optical fibers have a length determined in accordance with a layer of material deposited on the substrate from which the optical fibers are formed, a depth of the features in a mold or stamp and a number of processing/stamping steps. A method includes forming a layer on a substrate having a major surface, and processing the layer to form an array of optical fibers transversely disposed to the major surface.

These and other objects, features and advantages of the present disclosure will become apparent from the following detailed description of illustrative embodiments thereof, which is to be read in connection with the accompanying drawings.

This disclosure will present in detail the following description of preferred embodiments with reference to the following figures wherein:

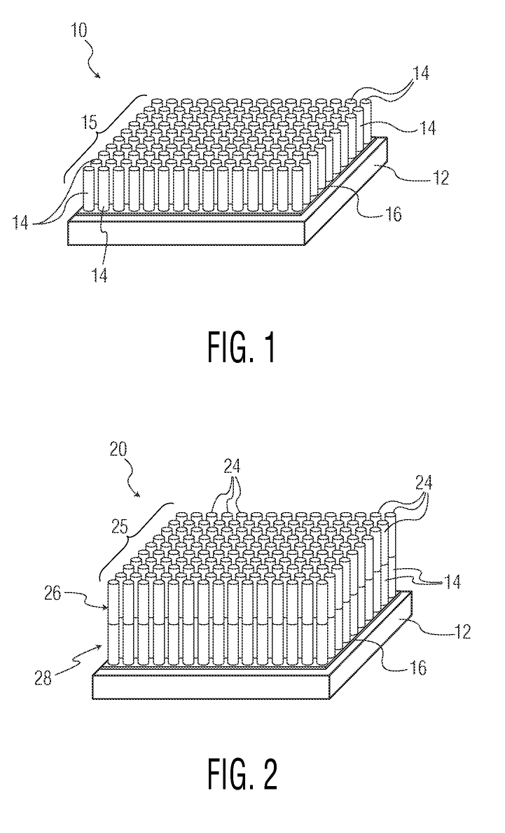

FIG. 1 is a perspective view of an optical faceplate embossed on a substrate in accordance with one embodiment;

FIG. 2 is a perspective view of an optical faceplate with stacked optical fibers embossed on a substrate in accordance with another embodiment;

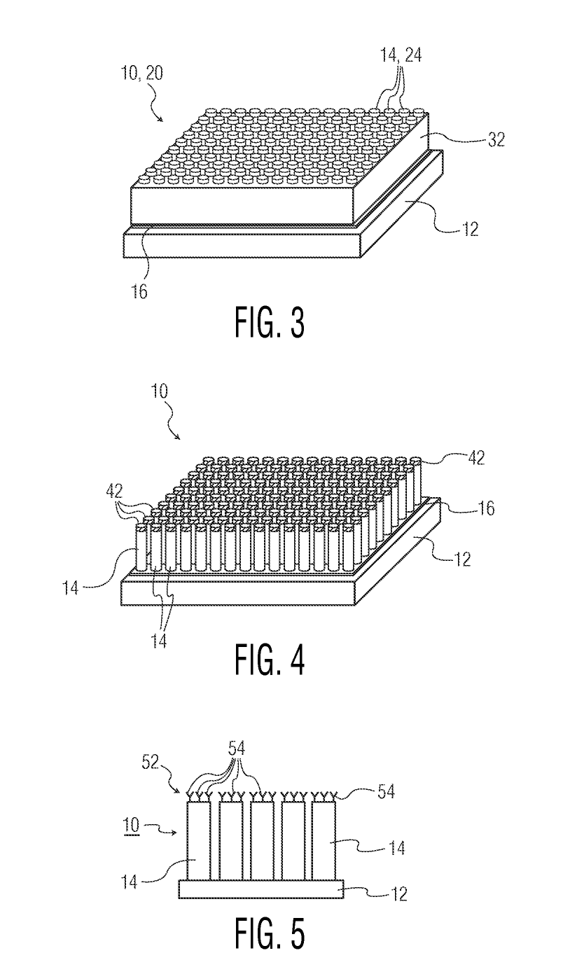

FIG. 3 is a perspective view of the optical faceplates of FIG. 1 or 2 having a light blocking material deposited in accordance with one embodiment;

FIG. 4 is a perspective view of an optical faceplate having a functional material (e.g., phosphorescent material) deposited on the optical fibers in accordance with one embodiment;

FIG. 5 is a perspective view of an optical faceplate having a functional material (e.g., target-specific affinity probes) deposited on the optical fibers in accordance with another embodiment;

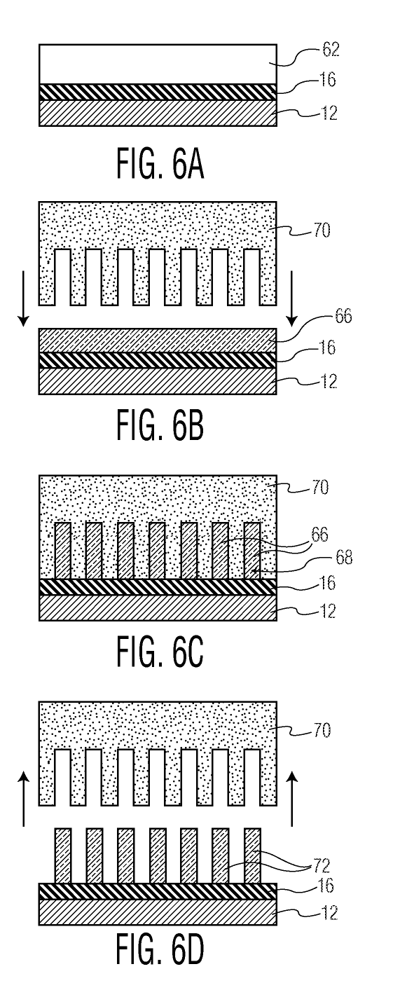

FIG. 6A is a cross-sectional view of a substrate having a solvent layer with activated molecules formed thereon;

FIG. 6B is a cross-sectional view of the solvent layer of FIG. 6A converted to a gel;

FIG. 6C is a cross-sectional view of the gel of FIG. 6B stamped using a rubber stamp to emboss fibers into a solid structure;

FIG. 6D is a cross-sectional view showing the solid structure forming optical fibers in accordance with one illustrative embodiment;

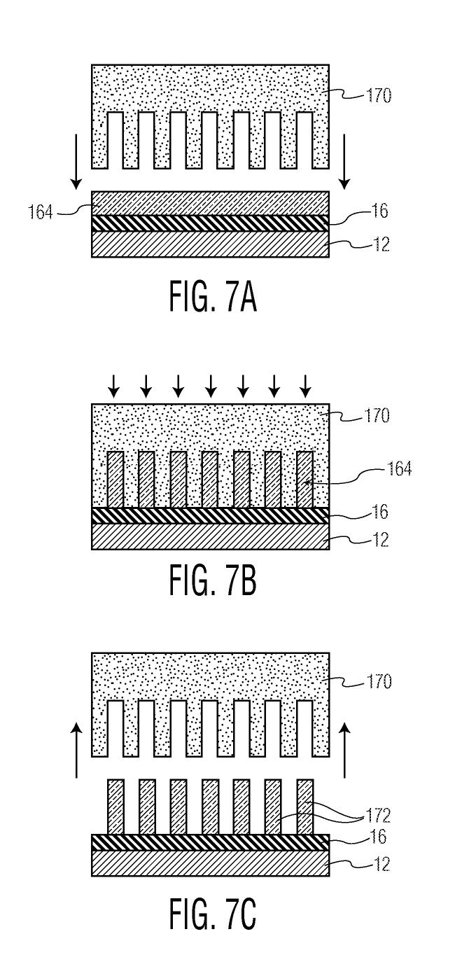

FIG. 7A is a cross-sectional view of a substrate having a UV or heat curable layer;

FIG. 7B is a cross-sectional view of the UV or heat curable layer of FIG. 7A imprinted using a template and subsequently irradiating the UV or heat curable layer with radiation to initiate polymerization;

FIG. 7C is a cross-sectional view showing the removal of the template leaving the solid structure forming optical fibers in accordance with one illustrative embodiment;

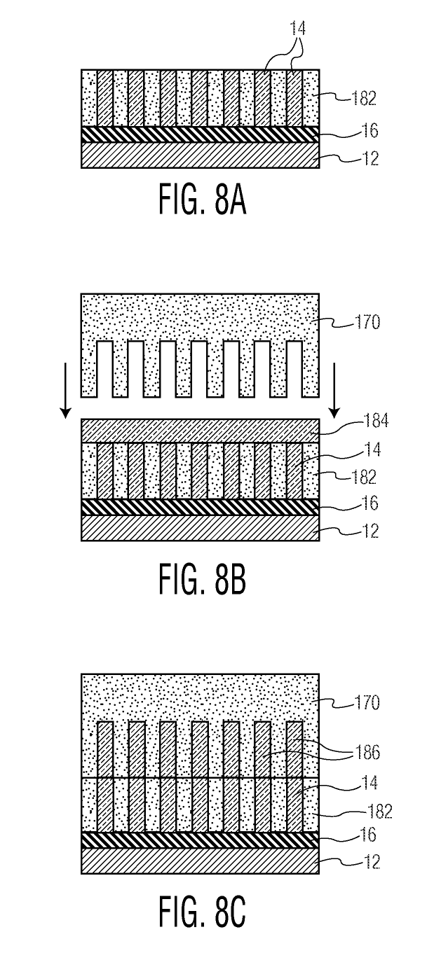

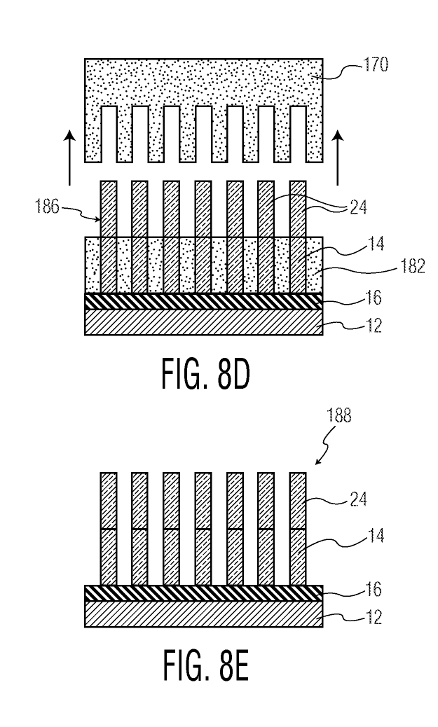

FIG. 8A is a cross-sectional view of a substrate having an array of optical fibers filled with a filling material;

FIG. 8B is a cross-sectional view of a substrate having the solid structure filled with a filling material having a layer to be imprinted formed thereon;

FIG. 8C is a cross-sectional view of the layer of FIG. 8B imprinted using a template and subsequently solidifying the curable resist;

FIG. 8D is a cross-sectional view showing the removal of the template leaving the solid structure forming optical fibers in accordance with one illustrative embodiment;

FIG. 8E is a cross-sectional view showing a solid stacked structure forming optical fibers in accordance with one illustrative embodiment after removal of the filling material;

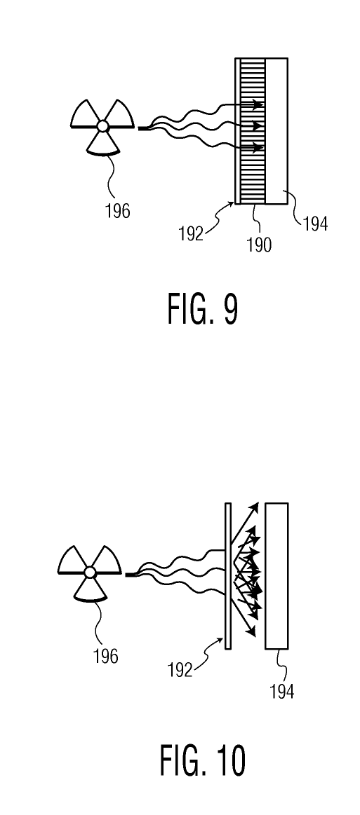

FIG. 9 is a schematic diagram showing an illustrative application of an optical faceplate in accordance with one illustrative embodiment;

FIG. 10 is a schematic diagram showing a set up without a face plate; and

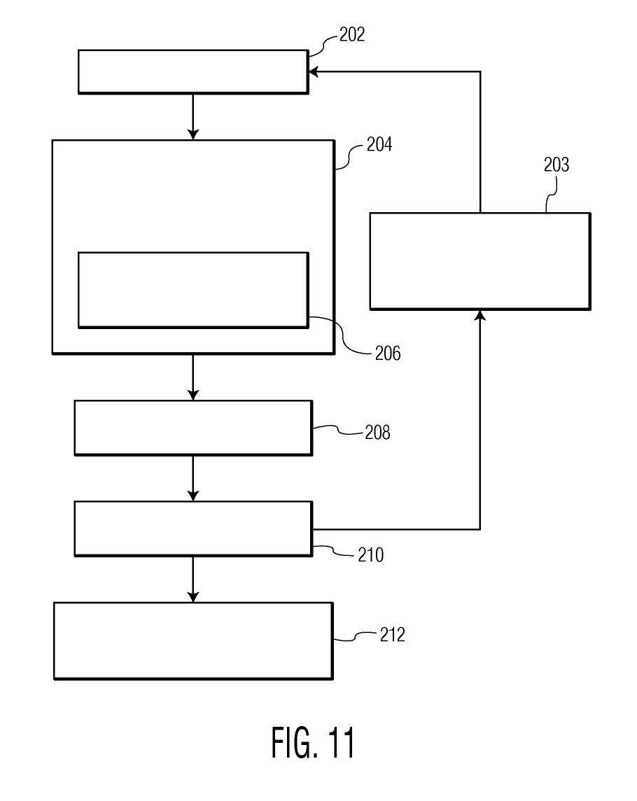

FIG. 11 is a block/flow diagram showing an illustrative method for fabricating an optical faceplate in accordance with the present principles.

The present disclosure describes optic faceplates which may be employed in applications including but not limited to charge-coupled device (CCD)/complementary metal oxide semiconductor (CMOS) coupling, laser array/fiber array coupling, cathode ray tube/liquid crystal display (CRT/LCD) displays, image intensification, remote viewings, field flattening, X-ray imaging such as radiography and mammography, and molecular diagnostics like in genomics, proteomics, drug discovery, micro-fluidic systems and others. Currently, such plates are produced by bundling thin optical fibers to a desired diameter, bonding them together followed by cutting and polishing the device to the desired thickness. This is a difficult process with various limitations. In accordance with the present principles, a method for manufacturing optical plates is disclosed. The method involves embossing a desired height and aspect ratio structure on top of a desired substrate which can be a functional unit (detector, etc.). This may be followed by filling areas around the embossed fibers if necessary with a low refractive material or other functional materials. Functional materials may be deposited on the fibers as well. These functional materials may include, for example, target-specific affinity probes deposited onto the optical faceplate.

It should be understood that the present invention will be described in terms of optical faceplates with embossed optical fibers. However, the teachings of the present invention are much broader and are applicable to array based attachment methods for fibers in a transverse orientation with respect to a substrate that carries or secures the fibers. The fibers may be mounted on, positioned on or otherwise placed on a substrate using a plurality of different technologies. Embodiments described herein are preferably fabricated using a printing process; however, lithographic imaging and processing may also be employed. Other processing techniques are also contemplated.

It should also be understood that the illustrative example of the optical faceplates may be adapted to include additional electronic/optical components. These components may be formed integrally with the substrate or mounted on the substrate or other components (e.g., on the fibers). In addition, the components employed may vary depending on the application and the design. The elements depicted in the FIGS. may be implemented in various combinations of hardware and provide functions which may be combined in a single element or multiple elements.

Referring now to the drawings in which like numerals represent the same or similar elements and initially to FIG. 1, an optical faceplate 10 includes a substrate 12 with a plurality of optical fibers 14 embossed on top of the substrate 12 in a desired pattern or array 15. The substrate 12 may be or have a functional unit 16 formed thereon, such as a pixel, array of pixels, a detector, a sensor, etc. If a detector or sensor is employed in substrate 12, quality checking or testing the fiber optic array 15 becomes easy since it is easier to detect the functionality of the final product. Fibers 14 preferably have high aspect ratios, e.g., width to length ratios of 1:2 to 1:10 or greater.

By printing or stamping the optical faceplate 10, described limitations in conventional bundling of the optical fibers, bonding them together followed by cutting and polishing them to a desired thickness, are advantageously addressed. The fibers 14 formed in accordance with the present principles, especially with smaller diameters (e.g., below 10 microns), are individually aligned and can be more easily manufactured. The method is also suitable for producing fibers with nanometer dimensions (nano-fibers). This method of manufacturing also permits the control of various array dimensions, e.g., center-to-center spacing between the fibers 14, the shape of the fibers (e.g. ovals, squares, hexagons, octagons, etc.), and fiber tip shapes. Such dimensions, shapes and spacings are advantageously predetermined in a die/stamp or pre-patterned in a lithographic masking operation.

It also should be understood that the present principles afford a great amount of flexibility in the fabrication of optical fibers. For example, the cross-sectional shapes of fibers and spacings between fibers may be varied over the same device or substrate. In other words, the fibers' density and individual sizes of fibers may be varied over a surface. Also, the cross-sectional shapes and widths may be varied and mixed over the surface. In addition, the top surface shape of the fibers can be varied to be dome shaped, flat, pyramidal, curved, etc. Furthermore, the dimensions of the fiber may also vary along the fiber axis. Such structures may be varied and mixed along the surface. For example, tapered fibers can also be produced.

Precise positioning of optical fibers 14 relative to the substrate 12 is advantageously achieved. For example, if substrate 12 includes a source or a detector such as CCD or CMOS sensors, precise positioning of fibers 14 can be provided at particular positions on the substrate 12 that can optimize or improve performance. Further, the bonding of an optical face plate to a source or detector is improved resulting in improved transmission efficiency, and reduced cost. Fibers can be bonded to the surface chemically. This can be achieved by treating the surface using reactive molecules which can subsequently react with the layer. It can also be just a physical adhesion.

Various materials can be used in the formation of fibers 14. In a particularly useful embodiment, a sol-gel material, which shows low polymerization shrinkage and becomes chemically attached to the surface, may be employed. In one embodiment, a liquid material is deposited (e.g., spun on) and solidified , by evaporation of the solvent and/or cross-linking by heat or light. For optical face plates 10, these materials have desired and improved optical properties (e.g. optimal numerical aperture, high transmission) for this application while being thermally and chemically stable (no degradation or discoloring). Examples of curable materials may be selected from the group of (metha)acrylate, epoxies oxetanes, vinyl ethers, alkoxides such as the alkoxysilanes tertramethoxysilane (TMOS), tetraethoxysilane (TEOS), methyltrimethoxysilane (MTMS) or other suitable materials.

Referring to FIG. 2, a stacked fiber optic faceplate 20 is illustratively shown. A first layer 28 includes a first material which may be deposited or spun onto a substrate 12. A second layer 26 is formed on top of the first layer 28. The processing of layers 26 and 28 may be performed in steps or performed simultaneously depending on the method used to process the layers and the types of materials employed for each layer. For example, if a stamping process is employed both layers 26 and 28 may be stamped at the same time to form stacked fibers 24. If a lithographic process is employed, the layers may be etched at the same time or etched in steps if the etching chemistry needs to be adjusted for the different layers.

Substrate 12 of FIG. 2 may include pixilated light sensors 16 such as CMOS or CCD devices formed in or on substrate 12. Fibers 24 are used to guide light to the sensors which are configured to guide light produced by for example a phosphor layer on top of the fibers. If the fibers need to have an aspect ratio which cannot be obtained in a single imprint action one can use a stacked fiber configuration shown in FIG. 2. Stacked fibers 24 may include different materials and have different optical characteristics and dimensions. One skilled in the art would understand that one of the layers may be employed to attenuate radiation (light, X-rays, etc.) or otherwise condition the light and/or radiation (e.g., filter a particular wavelength or the like). In one embodiment, layer 26 may remain continuous and not have fibers formed therein such that fibers are only formed in layer 28.

It should be understood that a plurality of layers may be stacked onto each other in a number greater than two. In addition, sections of the stacked fibers 24 may be formed coaxially as shown in FIG. 2; however, the sections of stacked fibers 24 may be formed with different cross-sectional areas from one layer to the next or may have centers offset from one layer to the next.

Referring to FIG. 3, an area between the fibers 14 or 24 may be left empty or filled or partially filled with a material 32. Material 32 may include a low refractive index material, a radiation blocking material (e.g., a light blocking material or an X-ray blocking material comprising heavy metals and their ions) or other functional material or structure. For example, a highly reflecting or absorbing material which may also comprise particles of any size may be used to fill the outer structure of the fiber optic faceplate 10 or 20 to obtain high image quality of a CCD or CMOS imager. Material 32 may also be employed to protect fibers 14 and 24 from stress/strain due to handling or operations. Material 32 may also be employed as a mask to protect lower portions of fibers 14 or 24 and present upper portions of the fibers 14 and 24 for processing (e.g., etching to clean rough or dirty surfaces or for forming additional features as described below, e.g., with reference to FIGS. 4 and 5).

Referring to FIG. 4, fiber optic face plate 10 (or 20) may includes a functional material 42 such as a luminescent or phosphorescent material (phosphors) or scintillator material or other materials in case an application includes X-ray imaging or other modalities. Preferably this material (e.g. phosphor) 42 may be positioned in an upper region of the fibers 14. These material structures 42 may be illuminated under given conditions.

Referring to FIG. 5, functional materials 52 such as, e.g., target-specific affinity probes 54 may be deposited onto the optical faceplate 10 or 20 as well. The target-specific affinity probes 54 can be deposited onto the optical faceplate 10 or 20 in a plurality of ways including contacting, dropping, spotting or by any other suitable deposition technique.

Immobilization of the target-specific affinity probes 54 onto the optic faceplate can be achieved in different ways including chemical binding of the probes 54 to the faceplate 10 or 20. Probes 54 may include different biological receptors for detecting DNA, RNA, proteins, cells, tissue, or any kind of biological molecule or organism of interest.

Optic faceplates can be used for high throughput methods of molecular diagnostics. The components may be employed in many applications, for example, genomics, proteomics, drug discovery and micro-fluidic systems to name a few. Optic faceplates have the advantage of having an extremely high number of optical elements and reaction sites. They provide interference free separation of reaction sites via microwells or capillaries. Using fiber optic technology, superior readout of individual optical channels can be obtained. This permits high sensitivity, repeatability and low background fluorescence.

Referring to FIGS. 6A-6D, an imprint lithography/embossing method is illustratively shown in accordance with one method for fabrication of optical faceplates in accordance with the present principles. A large-area imprint technology may be employed which is highly suitable for manufacturing down to nanometer size structures with high aspect ratios at room temperature in single and stacked layers. In accordance with this method, a flexible stamp, is employed for the replication of structures from mm to nm-size. This technique is extremely suitable for producing fiber optic faceplates since it can print features from mm up to nm-size with high aspect ratios at high accuracy. Furthermore, the manufacturing process is low-cost and has industrial manufacturing capability. The suggested manufacturing process producing fiber optic faceplates using imprint lithography is herein presented.

Referring to FIG. 6A, a solidifiable liquid 62 with reactive molecules, such as 2.9 wt % TMOS, 2.6 wt % MTMS, 87.5 wt % 1-propanol, 2.3 wt % formic acid, 3.7 wt % water and 1.0 wt % methylbenzoate, is applied on a substrate 12, e.g. by spincoating, spray coating or doctor blading. The substrate may include a functional unit 16, such as a pixel or optical sensor or the like. During this process, a solvent in liquid 62 evaporates, and the reactive molecules start forming a gel 66 as shown in FIG. 6B. Subsequently, a layer 68 is embossed by a flexible rubber stamp 70 which is gently applied to the substrate 12 in a wave type motion preventing air inclusions, as is described in WO2003099463 and EP 1511632, incorporated herein by reference, and depicted in FIG. 6C. The solvent in liquid 62 may also diffuse from the gel material 66 into the stamp 70 to assist in leaving a solid structure 72 on the substrate 12 and/or functional unit 16, as shown. The rubber stamp 70 is preferably removed by the wave type motion technique as well, peeling off of the stamp without destruction of the replica, as shown in FIG. 6D. If there is still some material left between structures 72, an etching method such as reactive ion etching (RIE) and/or ion beam etching may be employed. Optionally, the solid structure 72 on the substrate 12 can be filled by a light blocking or other material such as a silver sol-gel (see e.g., FIG. 3). It is also possible to manufacture the light blocking structures first, and subsequently filling the gaps with material that permits light to propagate therethrough.

Referring to FIGS. 7A-C, a second imprint lithography/embossing method is illustratively shown using ultraviolet (UV) or heat sensitive material for fabrication of an optical face plate.

Referring to FIG. 7A, a UV or heat sensitive material 164 is applied on a substrate 12, e.g. by spincoating or doctor blading. The deposited layer 164 is embossed or imprinted by a stamp 170 and is subsequently irradiated by radiation as is shown in FIG. 7B. The irradiation causes the resist or material 164 to crosslink or otherwise solidify. Removing the stamp 170 leaves a fiber structure 172 on the substrate 12, as shown in FIG. 7C.

Referring to FIG. 8, process steps used in producing a fiber stack structure in accordance with another illustrative embodiment are shown.

Referring to FIG. 8A, a fiber array 180 is formed on a substrate 12 including a functional unit 16. The fiber array 180 is produced by imprint lithography in which an area between the fibers 14 is filled with a material 182 (which may be the same as material 32 described above). Referring to FIG. 8B, a curable material 184 (e.g., a resist) is applied on the filled fiber array 180 of FIG. 8A, e.g. by spincoating or doctor blading. The deposited layer 184 of FIG. 8B is embossed by a stamp 170 after alignment of the stamp with respect to the substrate and is subsequently solidified to form solid structure 186 as is shown in FIG. 8C. Removing the stamp 170 leaves the fiber structure 186 on the filled fiber array 180 of FIG. 8A as shown in FIG. 8D. The filling material 182 can be removed afterwards by e.g. dissolving the filling material 182 in a suitable solvent or by burning away the filling material 182 resulting in a stacked fiber array 188 (only possible if heat or solvent resistant materials are used for producing the fiber array such as sol-gel materials).

Referring to FIG. 9, in one illustrative embodiment, a fiber optic faceplate 190 may be employed in a digital radiography application. This results in better image resolution and more efficient light collection and transmission compared to lenses. A fiber optical array 190 is positioned between a scintillator 192 and CCD or CMOS imagers 194. An X-ray source 196 produces X-rays. Light from an x-ray scintillator tends to scatter as depicted in FIG. 10, but a faceplate 190 made from coherent fiber optic strands in accordance with the present principles minimizes scatter and preserves image intensity and resolution.

Although the advantages of fiber optics for digital radiography are clear, problems may exist in manufacturing and bonding such fiber optic faceplates to scintillators and CCD or CMOS imagers using conventional technologies. It is important that the fibers are aligned with the pixels of the detector. Distortion and response non-uniformity, which degrade image quality, should be reduced. Higher degrees of alignment of the fibers with respect to pixels are achieved by bonding or embossing fibers to a substrate (e.g., directly to the CCD or CMOS imager) in accordance with the present principles. Precise, robust, reliable attachment is provided by stamping the fiber gel or using photolithography to cross-linked layers. In addition, higher image quality is provided by increasing the number of fibers delivering light to each sensor pixel. For example, a 6 micron fiber diameter can provide 16 fibers to a 24 micron pixel; however, many more fibers can be provided in accordance with the present principles, since fibers with a small diameter (even on the nanometer scale) can be manufactured. Density, size, shape and location of fibers can easily be varied across a substrate.

The present principles provide improved transmission efficiency, precise and robust attachment of the fiber optic faceplate, and decreased distortion and response non-uniformity to maximize image quality and durability. In addition, faceplates can be manufactured with fibers having specific shapes (e.g. ovals, squares, hexagons, octagons, etc.) and smaller sizes (e.g., below 15 micrometers and into the nano-meter range) as described above. Also the top surface shape of the fibers can be varied to be dome shaped, flat, pyramidal, curved, etc. Furthermore, the manufacturing method in accordance with the present embodiments is lower in cost.

In embodiments of the present invention, fiber optic faceplates have been manufactured using crosslinking materials. Micrometer and even nanometer structures with various shapes and high aspect ratios (1:10) have been produced on various surfaces having different roughness or profiles.

Referring to FIG. 11, a method for manufacturing an optical faceplate is illustratively depicted in accordance with the present principles. In block 202, a layer is formed on a major surface of a substrate. The layer is preferably a material, when cured/dried, capable of transmission of electromagnetic radiation at a desired wavelength or wavelength range. The layer may be spun unto or doctor bladed onto the surface of the substrate. The substrate may include an imaging device (e.g., pixel, etc.). The material may include a liquid which can be solidified or a cross-linking material, e.g., a liquid which becomes a gel after a solvent is evaporated or polymerized by heat or radiation. In one embodiment, the layer material can solidify during the embossing of the layer. In block 204, the layer is processed to form an array of optical fibers transversely disposed to the major surface of the substrate. This may include forming a gel or solid before or during an embossing step in block 206 or curing a resist layer during an embossing step using radiation (e.g., UV) or heat.

In an optional step 203, a filling material may be formed around the previous layer of fibers. This is so that a plurality of layers may be formed to create a stacked optical faceplate. After processing in blocks 202 through 210 is completed, as needed, filler material is applied instead of or in addition to the radiation blocking material (of block 210). A second layer (block 202) is formed and processed in accordance with steps 202, 204, 206, 208 and 210, as needed. This can continue for as many layers as needed. The plurality of the layers forms the array of optical fibers such that each layer provides a portion of a length of the entire optical fibers.

In block 206, the processing may include stamping or embossing the layer(s) to form the array of optical fibers. The stamping preferably includes applying the stamp with e.g. a wave like motion to avoid voids and air bubbles after alignment. The stamping process further includes controlling at least one of a spacing between fibers, a cross-sectional shape of the fibers and a tip geometry of the fibers. This may be performed using the features provided on the stamp.

In block 208, the array of fibers may be etched or heated to remove material between the fibers. Etching may include a reactive ion etch process, for example. In block 210, a radiation (light, X-rays, etc.) blocking material may be formed around the array of fibers. In block 212, a functional material may be deposited on an upper portion of the optical fibers. The functional material may include a phosphorescent or luminescent material and/or an affinity probe (e.g., a target-specific affinity probe). Other functional materials are also contemplated.

In interpreting the appended claims, it should be understood that:
a) the word “comprising” does not exclude the presence of other elements or acts than those listed in a given claim;
b) the word “a” or “an” preceding an element does not exclude the presence of a plurality of such elements;
c) any reference signs in the claims do not limit their scope;
d) several “means” may be represented by the same item or hardware or software implemented structure or function; and
e) no specific sequence of acts is intended to be required unless specifically indicated.

Having described preferred embodiments for an optical faceplate and method of manufacture (which are intended to be illustrative and not limiting), it is noted that modifications and variations can be made by persons skilled in the art in light of the above teachings. It is therefore to be understood that changes may be made in the particular embodiments of the disclosure disclosed which are within the scope and spirit of the embodiments disclosed herein as outlined by the appended claims. Having thus described the details and particularity required by the patent laws, what is claimed and desired protected by Letters Patent is set forth in the appended claims.

1. A method for manufacturing an optical faceplate, comprising:
forming (202) a layer on a substrate having a major surface; and
processing (206) the layer to form an array of optical fibers transversely disposed to and affixed to the major surface.

2. The method as recited in claim 1, wherein forming (202) a layer includes a component which forms crosslinks.

3. The method as recited in claim 1, wherein the layer which forms crosslinks includes one of a UV/heat curable layer and a gel layer.

4. The method as recited in claim 1, wherein forming (202) a layer includes forming (203) a plurality of layers and processing (204) the layer to form an array of optical fibers includes processing the plurality of the layers to form the array of optical fibers such that each layer provides a portion of a length of the optical fibers.

5. The method as recited in claim 1, wherein processing includes stamping (206) the layer to form the array of optical fibers.

6. The method as recited in claim 5, wherein stamping (206) includes employing a flexible stamp.

7. The method as recited in claim 5, wherein stamping (206) includes controlling at least one of a spacing between fibers, a cross-sectional shape of the fibers and a tip shape of the fibers.

8. The method as recited in claim 1, further comprising etching (208) the array of fibers to remove material between the fibers.

9. The method as recited in claim 1, further comprising forming (208) a radiation blocking material around the array of fibers.

10. The method as recited in claim 1, further comprising depositing (212) a functional material on an upper portion of the optical fibers.

11. The method as recited in claim 10, wherein depositing (212) the functional material on an upper portion of the optical fibers includes one of depositing a luminescent material, phosphorescent material, an affinity probe or a combination thereof

12. A method for manufacturing an optical faceplate, comprising:
applying (202) a layer on a substrate; and
embossing (206) the layer to form an array of optical fibers by applying a stamp and solidify the layer in the presence of the stamp.

13. The method as recited in claim 12, wherein the layer comprises a cross-linking material.

14. The method as recited in claim 12, wherein the layer includes a liquid material and further comprising at least partially solidifying (204) the layer before the embossing (206).

15. The method as recited in claim 12, further comprising forming (203) a plurality of layers and processing the layers to form a stacked array of optical fibers such that each of the plurality of layers provides a portion of a length of the optical fibers.

16. The method as recited in claim 12, further comprising etching (208) the array of fibers to remove material between the fibers.

17. The method as recited in claim 12, further comprising forming (210) a radiation blocking material around the array of fibers.

18. The method as recited in claim 12, further comprising depositing (212) a functional material on an upper portion of the optical fibers which includes one of a luminescent material, a phosphorescent material and an affinity probe.

19. An optical faceplate, comprising:
a substrate (12) having a major surface; and
an array (15) of optical fibers (14) embossed on the substrate, the optical fibers having a length determined by the layer thickness of material deposited on the substrate from which the optical fibers are formed and/or a depth of a feature on a stamp used to emboss the optical fibers.

20. The optical faceplate as recited in claim 19, wherein the substrate includes an optical sensor (16).

21. The optical faceplate as recited in claim 19, further comprising a radiation blocking material (32) formed around the array of fibers.

22. The optical faceplate as recited in claim 19, further comprising a functional material (42) on an upper portion of the optical fibers, which includes one of a phosphorescent material, a luminescent material and an affinity probe.

23. The optical faceplate as recited in claim 19, wherein the layer includes a plurality of layers (26, 28) and the length is determined in accordance with the plurality of layers.

24. The optical faceplate as recited in claim 19, wherein the optical fibers (14) include a width to length aspect ratio of at least 1:10.

25. The optical faceplate as recited in claim 19, wherein the optical fibers (14) have a non-circular cross-sectional shape.
